(19) United States
(12) Patent Application Publication
(10) Pub. No.: US 2022/0002858 A1
(43) Pub. Date: Jan. 6, 2022

(54) METAL MASK STRIP, METAL MASK PLATE, AND MANUFACTURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Qian JIANG, Wuhan, Hubei (CN); Yungsheng CHEN, Wuhan, Hubei (CN)

(21) Appl. No.: 16/759,272

(22) PCT Filed: Mar. 10, 2020
(86) PCT No.: PCT/CN2020/078538

§ 371 Date: Apr. 24, 2020

(30) Foreign Application Priority Data
Feb. 21, 2020 (CN) 202010106326.8

(51) Int. Cl. C23C 14/04

(52) U.S. Cl. CPC C23C 14/042; C23C 14/24

(57) ABSTRACT

The present invention provides a metal mask strip, a metal mask plate, and a manufacturing method thereof. The metal mask strip includes at least two mask sub-portions, which include: a non-light-transmitting region disposed at one end of the metal mask strip; a multiuse region disposed on a configuration side of a preset dividing line of a length of the metal mask strip, wherein the configuration side is on a same side as the non-light-transmitting region; and at least one light-transmitting region disposed between the non-light-transmitting region and the multiuse region.

### FIELD OF INVENTION

The present invention is related to the field of display technology, and specifically, to a metal mask strip, a metal mask plate, and a manufacturing method thereof.

### BACKGROUND OF INVENTION

Vacuum evaporation technology is inevitably used in manufacturing processes of display panels. The vacuum evaporation technology requires using metal mask plates. A metal mask plate includes a metal mask strip.

Currently, a width of the metal mask strip is determined by a width of a display panel, and a length of the metal mask strip is generally fixed. Research and development processes of the display panel and mass productions are generally separated. The research and development processes of the display panel use research and development lines. The research and development lines focus on product diversity development (in different sizes, different pixels, different functions) and verification. The mass productions use mass production lines. The mass production lines are used to mass-produce designated display panels. However, a length of a metal mask strip for the research and development lines and a length of a metal mask strip for the mass production lines are different, and the metal mask strip for the research and development lines and the metal mask strip for the mass production lines are independent of each other, so they not technically compatible. Therefore, they need to be manufactured separately, which decreases a production efficiency and addition increases production costs.

Therefore, it is necessary to provide a metal mask strip, a metal mask plate, and a manufacturing method thereof to solve problems of the prior art.

### SUMMARY OF INVENTION

A purpose of the present invention is to provide a metal mask strip, a metal mask plate, and a manufacturing method thereof, which can increase production efficiency and reduce production costs.

In order to solve the above technical problems, the present invention provides a metal mask strip including at least two mask sub-portions. Each of the mask sub-portions includes:

a non-light-transmitting region disposed at one end of the metal mask strip;

a multiuse region disposed on a configuration side of a preset dividing line of a length of the metal mask strip, wherein the configuration side is on a same side as the non-light-transmitting region; and

at least one light-transmitting region disposed between the non-light-transmitting region and the multiuse region.

The present invention further provides a manufacturing method of a metal mask plate including:

forming a metal mask strip including at least two mask sub-portion, wherein each of the mask sub-portions includes: a non-light-transmitting region disposed at one end of the metal mask strip; a multiuse region disposed on a configuration side of a preset dividing line of a length of the metal mask strip, wherein the configuration side is on a same side as the non-light-transmitting region; and at least one light-transmitting region disposed between the non-light-transmitting region and the multiuse region;

cutting the metal mask strip along the preset dividing line to form mask sub-portions; and welding the mask sub-portions on a support frame to form a metal mask plate having a first length.

and/or welding the metal mask strip on the support frame to form a metal mask plate having a second length; wherein the second length is greater than the first length.

The present invention further provides a glass mask. The glass mask is used to manufacture a metal mask strip. The metal mask strip includes at least two mask sub-portions. Each of the mask sub-portions includes: a non-light-transmitting region disposed at one end of the metal mask strip; a multiuse region disposed on a configuration side of a preset dividing line of a length of the metal mask strip, wherein the configuration side is on a same side as the non-light-transmitting region; and at least one light-transmitting region disposed between the non-light-transmitting region and the multiuse region.

The glass mask includes a patterned region and a non-patterned region. The patterned region corresponds to the light-transmitting region and the multiuse region. The non-patterned region corresponds to the non-light-transmitting region.

The metal mask strip, the metal mask plate, and the manufacturing method thereof of the present invention include at least two mask sub-portions. Each of the mask sub-portions includes: the non-light-transmitting region disposed at one end of the metal mask strip; the multiuse region disposed on the configuration side of the preset dividing line of the length of the metal mask strip, wherein the configuration side is on the same side as the non-light-transmitting region; and at least one light-transmitting region disposed between the non-light-transmitting region and the multiuse region. Because the metal mask strip can be prepared for a mask plate of a first production line and a mask plate of a second production line, the production costs is reduced, and the production efficiency is increased.

### DESCRIPTION OF DRAWINGS

FIG. 1 is a structural diagram of a first step of manufacturing method of a first type of a metal mask plate in the prior art.

FIG. 2 is a structural diagram of a second step of manufacturing method of the first type of the metal mask plate in the prior art.

FIG. 3 is a structural diagram of a first step of manufacturing method of a second type of a metal mask plate in the prior art.

FIG. 4 is a structural diagram of a second step of manufacturing method of the second type of the metal mask plate in the prior art.

FIG. 5 is a structural diagram of a metal mask strip in the prior art.

FIG. 6 is an enlarged view of light-transmitting regions in FIG. 5.

FIG. 7 is a structural diagram of a metal mask strip of an embodiment of the present invention.

FIG. 8 is another structural diagram of the metal mask strip of the embodiment of the present invention.

FIG. 9 is a structural diagram of a metal mask strip of another embodiment of the present invention.

FIG. 10 is a structural diagram of the metal mask strip in FIG. 7 after cutting of the present invention.

FIG. 11 is a structural diagram of a glass mask of an embodiment of the present invention.

FIG. 12 is a structural diagram of a glass mask of another embodiment of the present invention.

FIG. 13 is a structural diagram of a manufacturing method of a metal mask strip of an embodiment of the present invention.

### DETAILED DESCRIPTION OF PREFERRED EMBODIMENTS

Examples are described below with reference to the appended drawings, and the drawings illustrate particular embodiments in which the present invention may be practiced. Directional terms mentioned in the present invention, such as “upper”, “lower”, “front”, “rear”, “left”, “right”, “in”, “out”, “side”, etc., only refer to directions in the accompanying drawings. Thus, the adoption of directional terms is used to describe and understand the present invention, but not to limit the present invention. In the drawings, units of similar structures are represented using the same numerals.

In the specification, the claims, and the accompanying drawings, the terms “first”, “second”, and so on are intended to distinguish between similar objects, rather than indicate a specific order or a time order. Moreover, the terms “include”, “have” and any variant thereof mean to cover the non-exclusive inclusion.

An organic light-emitting diode (OLED) display panel is taken as an example. Thin-films of the display panel are manufactured by vacuum evaporation technology. An organic material or a metal material are heated in a vacuum environment (around 10⁻⁵ Pa), the materials are sublimated by heat, and an organic thin-film or a metal thin-film with a certain shape are formed on a surface of a substrate through metal mask plate having a pattern. Through continuous deposition and film formation of multiple materials, the display panel with multiple thin-films can be formed.

The metal mask plate includes a universal metal mask plate and a precision metal mask plate. Structures of the universal metal mask plate and the precision metal mask plate both include a metal frame and a metal mask strip fixed on the metal frame. A thickness of the metal mask strip ranges from 10 to 100 um (a common thickness includes 20 um, 25 um, and 30 um). The metal mask strip is fixed on the metal frame by laser welding.

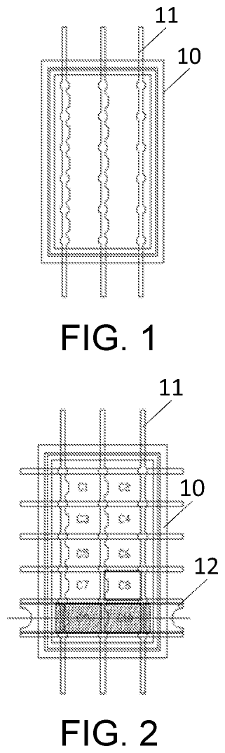

Normally, the precision metal mask plate is manufactured by following methods. As shown in FIG. 1, firstly, a first method welds a plurality of metal strips 11 having support and shielding functions on a metal frame 10. A width of the metal strip 11 ranges from 2 to 30 mm, and a specific width can be determined according to an actual requirement. A thickness of the metal strip 11 ranges is 50 um or 100 um. The metal strips 11 are arranged along a vertical direction. As shown in FIG. 2, secondly, they are stretched, and a precision metal mask strip 12 is welded on the metal frame 10. After welding one precision metal mask strip 12, then they are stretched again, and next precision metal mask strip 12 (hereinafter referred to as metal mask strip) is welded. Metal mask strips 12 are arranged along a horizontal direction. the metal mask strips 12 and the metal strips 11 define vapor deposition regions C1 to C10. A number of rows and columns of the vapor deposition regions are not limited, and FIG. 1 only shows the vapor deposition regions 01 to 010.

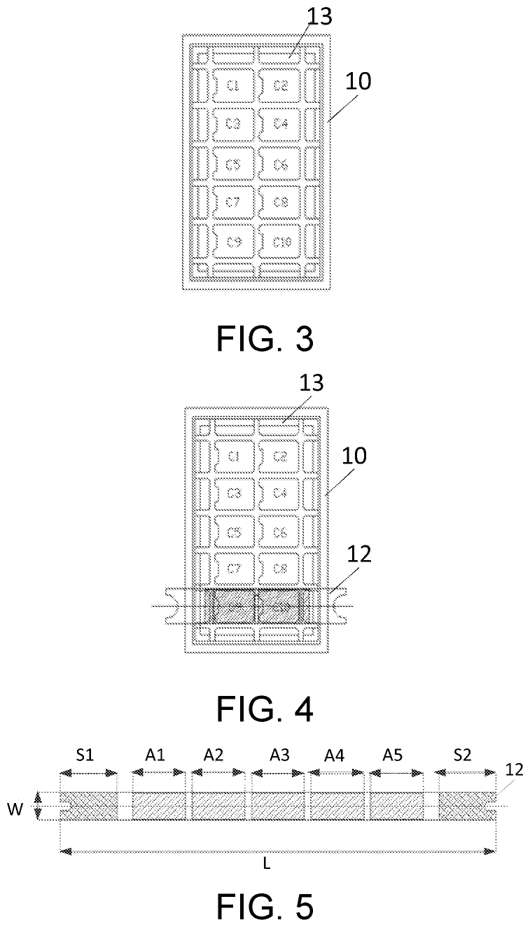

As shown in FIGS. 3 and 4, firstly, a second method welds a web support 13 on the metal frame 10. secondly, they are stretched, and a metal mask strip 12 is welded on the metal frame 10. After welding one metal mask strip 12, then they are stretched again, and next metal mask strip 12 is weld. Only one metal mask strip 12 is shown in FIGS. 2 and 4. The number of rows and columns of the vapor deposition regions are not limited, and figures only show the vapor deposition regions 01 to 010.

As shown in FIG. 5, a metal mask strip 12 in the prior includes two non-light-transmitting regions S1 and S2 and light-transmitting regions A1 to A5. The light-transmitting regions A1 to A5 are disposed between the non-light-transmitting regions S1 and S2. Widths of the light-transmitting regions A1 to A5 are less than a width W of the metal mask strip 12. Ends of the non-light-transmitting regions S1 and S2 are provided with U-shaped openings. Clamp regions are disposed above and below the U-shaped opening. Ends of the non-light-transmitting regions S1 and S2 close to outer sides are ends of the metal mask strip 12, and ends thereof close to inner sides are positions of preset cutting lines. A length L of the metal mask strip 12 ranges around 1200 mm, and a specific size is not limited.

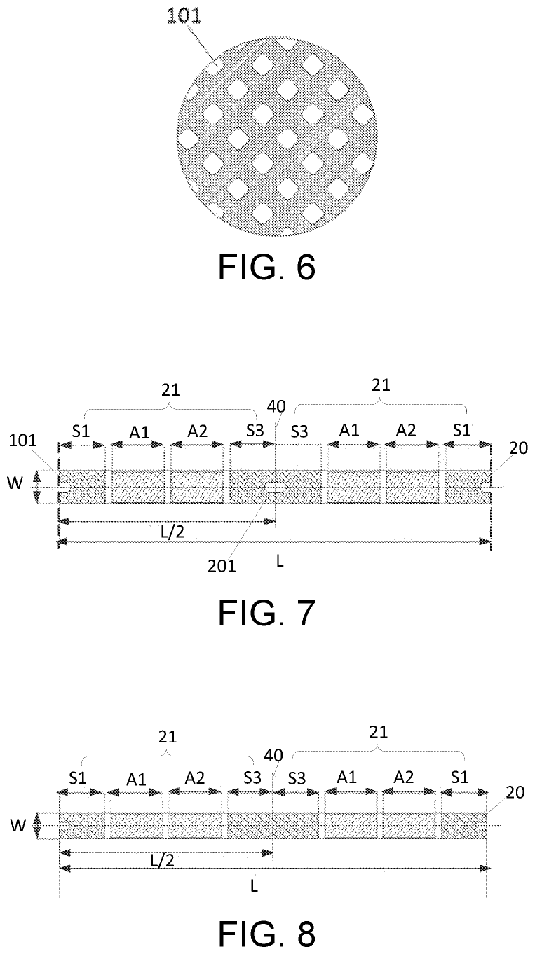

FIG. 6 is an enlarged view of the light-transmitting regions A1 to A5 in FIG. 5. Each light-transmitting region is provided with a plurality of precision holes 101, which means that they form a precision array hole region. Other light-transmitting regions are same as this, which is not repeated herein.

Returning to FIG. 5, there can be a non-light-transmitting region (i.e., metal materials) or a light-transmitting region between two adjacent light-transmitting regions. When a light-transmitting region is disposed between two adjacent light-transmitting regions, the above light-transmitting regions A1 to A5 become connected precision array hole regions. A size and a number of the light-transmitting regions are not limited and are determined according to the display panel.

Production lines of the display panel determine the length L of the metal mask strip 12, and the width W thereof is not limited, which is determined by a width of the display panel. For example, the length L of the metal mask strip 12 for the mass production lines is generally around 1200 mm, and the length L of the metal mask strip 12 for the research and development lines is generally around 650 mm.

Material of the metal mask strip 12 can be an iron-nickel alloy, the length thereof is L, the width thereof is W, the thickness thereof ranges from 10 to 30 um, and a preferable thickness is one of 20 um, 25 um, and 30 um.

Please refer to FIGS. 7 and 8, FIG. 7 is a structural diagram of a metal mask strip of an embodiment of the present invention.

As shown in FIG. 7, each metal mask strip 20 includes two mask sub-portions 21. One of the mask sub-portions 21 is disposed on one side (left side) of the metal mask strip 20. The other one of the mask sub-portions 21 is disposed on the other side (right side) of the metal mask strip 20. The two mask sub-portions 21 are disposed opposite to each other. in an embodiment, lengths of the two mask sub-portions 21 are equal, so this is convenient to adapt the metal mask strip 20 to a first production line and a second production line at a same time. Of course, in another embodiment, the length of the two mask sub-portions 21 can be different. In an embodiment, the first production line is the research and development line, and the second production line is the mass production line.

Each of the mask sub-portions 21 includes: a non-light-transmitting region S1, a multiuse region S3, and two light-transmitting regions A1 and A2. The non-light-transmitting region S1 is disposed at one end of the metal mask strip 20. A specific structure of the non-light-transmitting region S1 can refer to FIG. 6. A first opening 101 is defined at a configuration end of the non-light-transmitting region S1. The configuration end is an outer end. A plane shape of the first opening 101 can be a U-shaped. Length of the non-light-transmitting region S1 and the multiuse region S3 can be equal or different.

The multiuse region S3 is disposed on a configuration side of a preset dividing line 40 of a length of the metal mask strip 20. The configuration side is on a same side as the non-light-transmitting region S1. The preset dividing line 40 can be a center dividing line of the length of the metal mask strip 20. A mask sub-portion on a left side is taken as an example. When the non-light-transmitting region S1 is disposed on a left side of the metal mask strip 20, the multiuse region S3 is disposed on a left side of the center dividing line of the length of the metal mask strip 20. When the non-light-transmitting region S1 is disposed on a right side of the metal mask strip 20, the multiuse region S3 is disposed on a right side of the center dividing line of the length of the metal mask strip 20. In an embodiment, an area of the multiuse region S3 is greater than a preset area. The preset area can be determined according to a value from experiences, so that the metal mask strip 20 is more firmly fixed on a support frame. In an embodiment, in order to simplify manufacturing processes, the areas of the multiuse region S3 and the non-light-transmitting region S1 are equal. In an embodiment, a second opening 201 is defined at an end of the multiuse region S3 opposite to the configuration end. The first opening 101 is arranged corresponding to the second opening 201. A plane shape of the second opening 101 can also be a U-shaped. However, because the thickness of the metal mask strip 20 is too thin, breakages are prone to occur near the openings between two adjacent multiuse regions S3 during a production of a movement. In order to avoid this problem, in other embodiments, as shown in FIG. 8, the multiuse region S3 can not be provided with an opening.

In an embodiment, the non-light-transmitting region S1 and the multiuse region S3 are disposed opposite to each other in a same mask sub-portion 21. The mask sub-portion 21 on the left side is taken as an example. The non-light-transmitting region S1 is disposed on a left end of the mask sub-portion 21, and the multiuse region S3 is disposed on a right end of the mask sub-portion 21.

The light-transmitting regions A1 and A2 are disposed between the non-light-transmitting region S1 and the multiuse region S3. In an embodiment, the two adjacent light-transmitting regions A1 and A2 can be spaced apart. In this way, a gap between the two adjacent light-transmitting regions A1 and A2 is a non-light-transmitting region. Of course, the two adjacent light-transmitting regions A1 and A2 can also be disposed without spacing, which means that the two adjacent light-transmitting regions A1 and A2 are connected to form a light-transmitting region in an embodiment, the two adjacent light-transmitting regions A1 and A2 can be spaced apart or disposed without spacing. The multiuse region S3 and the light-transmitting regions A2 can be spaced apart of disposed without spacing. Understandably, a number of light-transmitting regions in each of the mask sub-portions is not limited to this.

The metal mask strip 20 in this embodiment is used for the first production line (e.g., the research and development lines). The multiuse region S3 is a non-light-transmitting region.

Understandably, each metal mask strip can include more than two mask sub-portions. At this time, the preset dividing line 40 can be a dividing line for dividing the length of the metal mask strip 20 into thirds or other dividing lines. Thus, the preset dividing line 40 can be a dividing line for dividing the length into less than or greater than seconds.

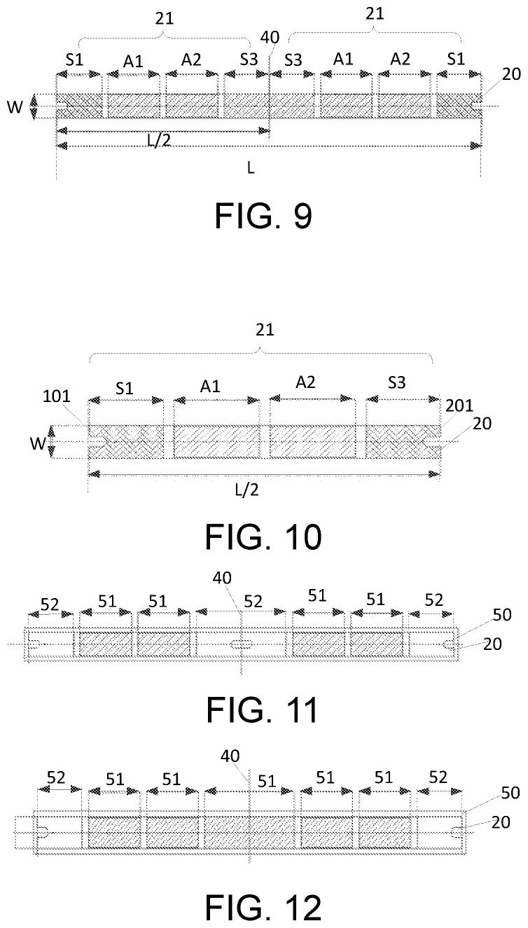

Please refer to FIG. 9, FIG. 9 is a structural diagram of a metal mask strip of another embodiment of the present invention.

As shown in FIG. 9, a difference between this embodiment and the metal mask strip in FIG. 8 is that the multiuse region S3 of the metal mask strip of this embodiment is a light-transmitting region. The metal mask strip 20 in this embodiment is used for the second production line such as the mass production lines. When the metal mask strip 20 is used for the second production line, the multiuse region S3 is a light-transmitting region.

The present invention further provides a metal mask plate including: a plurality of any of the metal mask strips 20 described above and a support frame. The plurality of the metal mask strips 20 are disposed on the support frame.

The present invention further provided a manufacturing method of a metal mask plate including the following steps.

S101, forming a metal mask strip.

For example, the metal mask strip 20 shown in FIGS. 7 and 8 is formed. For a specific structure, please refer to the above description.

S102, cutting the metal mask strip along the preset dividing line to form mask sub-portions and welding the mask sub-portions on a support frame to form a metal mask plate having a first length.

For example, the metal mask strip 20 is provided with a cutting line, which is determined along the preset dividing line 40. The metal mask strip in FIG. 7 is taken as an example. The mask sub-portions 21 are formed through cutting (i.e., laser cutting) the metal mask strip 20 along the preset dividing line 40, which is shown in FIG. 10. Understandably, after forming the mask sub-portions 21 through cutting the metal mask strip in FIG. 8 along the preset dividing line 40, an opening can be processed at an outer end of the multiuse region S3 by laser cutting. Accordingly, two mask sub-portions 21 having a same length can be formed after cutting.

The mask sub-portions 21 are welded on the support frame to form the metal mask plate having the first length. A specific manufacturing process can refer to FIGS. 1 to 4, which is not repeated herein.

In addition, the above methods can further include:

S103, welding the metal mask strip on the support frame to form a metal mask plate having a second length.

For example, the above metal mask strip 20 is not cut, and any one of the metal mask strips in FIGS. 7 and 8 is directly welded on the support frame to form the metal mask plate having the second length. The second length is greater than the first length.

After the metal mask strips for the research and development lines in FIGS. 7 and 8 are cut at L/2 position, they can be applied in the research and development lines of the display panel and is stretched and welded to manufacture the metal mask plate. If they are not cut, they can be applied in the mass production lines of the display panel. For example, the second length is 1300 mm, and the first length is 650 mm. In other embodiments, the second length is three times or four times the first length, which is not limited herein.

For example, a meal mask strip having a length of 1300 mm can be applied in the mass production lines and is stretched and welded to obtain a metal mask plate for the mass production lines. After cutting, two metal mask strips having a length of 650 mm shown in FIG. 10 is manufactured, and they can be directly applied in the research and development lines of the display panel and is stretched and welded to obtain the metal mask plate for the research and development lines. Thus, the metal mask strip is compatible with the research and development lines and the mass production lines. Of course, in other embodiments, the manufacturing method of the metal mask plate can include a first step and a third step.

The following describes the first step of the above method, which is a manufacturing method of the metal mask strips.

When manufacturing the metal mask strip shown in FIGS. 7 to 9, a corresponding glass mask needs to be preferentially manufactured. As shown in FIG. 11, a size of the glass mask 50 is slightly greater than a size of the metal mask strip 20. In an embodiment, the glass mask 50 includes a patterned region 51 (a partially light-transmitted region or a patterned region) and a non-patterned region 52 (a fully light-transmitted region). A position of the glass mask 50 corresponding to the light-transmitting region of the metal mask strip 20 is provided with a corresponding patterned region 51. A position of the glass mask 50 corresponding to the non-light-transmitting region is not provided with any patterns to form a fully light-transmitted region or the non-patterned region 52. A position of the glass mask 50 corresponding to the multiuse region S3 is not provided with any patterns as well. The glass mask 50 can be provided with marks of horizontal cutting lines and vertical cutting lines. The cutting lines are determined according to an actual requirement.

In another embodiment, as shown in FIG. 12, the position of the glass mask 50 corresponding to the multiuse region S3 is the patterned region 51, which means that the position of the glass mask 50 corresponding to the multiuse region S3 is provided with patterns.

In order to manufacture the above metal mask strips in the FIGS. 7 and 8, corresponding glass masks must be manufactured, and costs of the glass masks are high. For example, the above glass mask in FIG. 11 can only manufacture the metal mask strip 20 shown in FIGS. 7 and 8, resulting in a low utilization rate of the glass mask and increasing production costs. The following methods can solve this problem.

A first method: using the glass mask shown in FIG. 11 to manufacturing the metal mask strip shown in FIG. 8. After cutting the metal mask strip along the dividing line at the L/2 position, it is introduced into the research and development lines for verification and testing. After the verification and the testing of the research and development lines are passed, a small amount of metal mask strips shown in FIG. 8 without cutting are imported into the mass production lines for a small amount of verification and testing. After the small amount of the verification and the testing of the mass production lines is passed, the above glass mask is patterned again, so that the position of the glass mask corresponding to the multiuse region S3 of the metal mask strip 20 forms the partially light-transmitted region. A supplier patterns the multiuse region S3 of the metal mask strip 20 shown in FIG. 8 through a patterned glass mask to form the precision array hole region, which forms the light-transmitting region and obtains the metal mask strip 20 shown in FIG. 9 for a panel manufacturer to directly introduce into the mass production lines.

Because only one glass mask is needed, after manufacture the metal mask strip 20 for the research and development lines, the glass mask is re-processed (patterning). Then, the metal mask strip 20 for the mass production lines is manufactured by the processed glass mask. This method requires a second processing of the glass mask.

A second method: the metal mask strips 20 in FIGS. 7 to 9 are manufactured by the glass mask shown in FIG. 12.

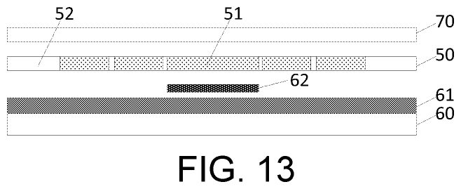

With reference to FIG. 13, numeral 60 indicates a metal layer, and numeral 61 indicates a photoresist layer. Material of the metal layer 60 can be an iron-nickel alloy. Numeral 62 indicates a shielding plate 62 disposed between the photoresist layer 61 and the glass mask 50. Numeral 70 indicates a light source on the other side of the glass mask 50. The light source 70 emits short-wavelength colored light (generally UV light) and projects on the photoresist layer 61 through the glass mask 50. Patterns in the patterned region 51 of the glass mask 50 is projected on the photoresist layer 61, so the patterns are transferred to the photoresist layer 61. However, because the light is blocked at a position corresponding to the shielding plate 62, the patterns cannot be transferred to the photoresist layer 61, which means that the photoresist layer under the shielding plate 62 has no pattern. After an exposure process, a development process, and an etching process, the metal mask strip 20 shown in FIGS. 7 and 8 can be manufactured. In particular, the shielding plate 62 can also be designed to allow partial region to transmit light.

During the exposure process, the shielding plate 62 is removed, and all the patterns on the glass mask 50 are projected on the photoresist layer 61. After the exposure process, the development process, and the etching process, the metal mask strip shown in FIG. 9 can be manufactured. With this method, only one glass mask needs to be purchased, and no secondary processing of the glass mask is required, which improves the utilization rate of the glass mask and effectively reduces production costs. In addition, total costs of the research and development processes and the mass productions of new display panels is reduced, and the metal mask strip for the research and development lines and the metal mask strip for the mass production lines are simultaneously manufactured.

The metal mask strip, the metal mask plate, and the manufacturing method thereof of the present invention include at least two mask sub-portions. Each of the mask sub-portions includes: the non-light-transmitting region disposed at one end of the metal mask strip; the multiuse region disposed on the configuration side of the preset dividing line of the length of the metal mask strip, wherein the configuration side is on the same side as the non-light-transmitting region; and at least one light-transmitting region disposed between the non-light-transmitting region and the multiuse region. Because the metal mask strip can be applied in the first production line and the second production line, the production costs is reduced, and the production efficiency is increased.

Although the present invention has been disclosed above with the preferred embodiments, it is not intended to limit the present invention. Persons having ordinary skill in this technical field can still make various alterations and modifications without departing from the scope and spirit of this invention. Therefore, the scope of the present invention should be defined and protected by the following claims and their equivalents.

What is claimed is:

1. A metal mask strip, comprising at least two mask sub-portions, wherein each of the mask sub-portions comprises:
a non-light-transmitting region disposed at one end of the metal mask strip;
a multiuse region disposed on a configuration side of a preset dividing line of a length of the metal mask strip, wherein the configuration side is on a same side as the non-light-transmitting region; and
at least one light-transmitting region disposed between the non-light-transmitting region and the multiuse region.

2. The metal mask strip according to claim 1, wherein the metal mask strip comprises two mask sub-portions, one of the mask sub-portions is disposed on one side of the metal mask strip, and the other one of the mask sub-portions is disposed on the other side of the metal mask strip.

3. The metal mask strip according to claim 2, wherein lengths of the two mask sub-portions are equal.

4. The metal mask strip according to claim 1, wherein the multiuse region is a non-light-transmitting region when the metal mask strip is used in a first production line; and
the multiuse region is a light-transmitting region when the metal mask strip is used in a second production line.

5. The metal mask strip according to claim 1, wherein a first opening is defined at a configuration end of the non-light-transmitting region, a second opening is defined at an end of the multiuse region opposite to the configuration end, and the first opening is arranged corresponding to the second opening.

6. The metal mask strip according to claim 1, wherein an area of the multiuse region is greater than a preset area.

7. The metal mask strip according to claim 1, wherein the preset dividing line comprises a center dividing line.

8. The metal mask strip according to claim 1, wherein an area of a light-transmitting region in a first sub-portion is equal to an area of a light-transmitting region in a second sub-portion.

9. A metal mask plate, comprising a metal mask strip comprising at least two mask sub-portion, wherein each of the mask sub-portions comprises:
a non-light-transmitting region disposed at one end of the metal mask strip;
a multiuse region disposed on a configuration side of a preset dividing line of a length of the metal mask strip, wherein the configuration side is on a same side as the non-light-transmitting region; and
at least one light-transmitting region disposed between the non-light-transmitting region and the multiuse region.

10. The metal mask plate according to claim 9, wherein the metal mask strip comprises two mask sub-portions, one of the mask sub-portions is disposed on one side of the metal mask strip, and the other one of the mask sub-portions is disposed on the other side of the metal mask strip.

11. The metal mask plate according to claim 10, wherein lengths of the two mask sub-portions are equal.

12. The metal mask plate according to claim 9, wherein the multiuse region is a non-light-transmitting region when the metal mask strip is used in a first production line; and
the multiuse region is a light-transmitting region when the metal mask strip is used in a second production line.

13. The metal mask plate according to claim 9, wherein a first opening is defined at a configuration end of the non-light-transmitting region, a second opening is defined at an end of the multiuse region opposite to the configuration end, and the first opening is arranged corresponding to the second opening.

14. The metal mask plate according to claim 9, wherein an area of the multiuse region is greater than a preset area.

15. The metal mask plate according to claim 9, wherein the preset dividing line comprises a center dividing line.

16. The metal mask plate according to claim 9, wherein an area of a light-transmitting region in a first sub-portion is equal to an area of a light-transmitting region in a second sub-portion.

17. A manufacturing method of a metal mask plate, comprising:
forming a metal mask strip comprising at least two mask sub-portion, wherein each of the mask sub-portions comprises:
a non-light-transmitting region disposed at one end of the metal mask strip;
a multiuse region disposed on a configuration side of a preset dividing line of a length of the metal mask strip, wherein the configuration side is on a same side as the non-light-transmitting region; and
at least one light-transmitting region disposed between the non-light-transmitting region and the multiuse region;
cutting the metal mask strip along the preset dividing line to form mask sub-portions; and
welding the mask sub-portions on a support frame to form a metal mask plate having a first length.

18. The manufacturing method of the metal mask plate according to claim 17, further comprising:
welding the metal mask strip on the support frame to form a metal mask plate having a second length;
wherein the second length is greater than the first length.

19. The manufacturing method of the metal mask plate according to claim 18, wherein the metal mask plate having the second length is used on a second production line; and
the metal mask plate having the first length is used on a first production line.

20. The manufacturing method of the metal mask plate according to claim 19, wherein the metal mask strip used in the first production line and the metal mask strip used in the second production line are both made through a same glass mask.
